(19) United States
(12) Patent Application Publication
(10) Pub. No.: US 2013/0052830 A1
(43) Pub. Date: Feb. 28, 2013

(54) PLASMA REACTOR HAVING DUAL INDUCTIVELY COUPLED PLASMA SOURCE

(71) Applicants: Gyoo-Dong KIM, Yongin-si (KR); Dae-Kyu Choi, Yongin-si (KR)

(72) Inventors: Gyoo-Dong KIM, Yongin-si (KR); Dae-Kyu Choi, Yongin-si (KR)

(21) Appl. No.: 13/337,860

(22) Filed: Dec. 27, 2011

(30) Foreign Application Priority Data
Aug. 31, 2011 (KR) 10-2011-0087908

(51) Int. Cl. H01L 21/768; C23C 16/455; H01L 21/3065

(52) U.S. Cl. 438/700; 156/345.1; 156/345.37; 156/345.33; 257/E21.577

(57) ABSTRACT

Provided is a plasma reactor having a dual inductively coupled plasma source that includes a plasma reactor body having a substrate processing area and a dielectric window which comes in contact with the substrate processing area; and a plasma source including a first antenna for providing first induced electromotive force for generating plasma onto a central area of the substrate processing area through the dielectric window and a second antenna for providing second induced electromotive force for generating the plasma onto an outer area of the substrate processing area, wherein a TSV is formed at a target substrate within the substrate processing area by repeatedly performing a deposition process and an etch process using the plasma generated through the dual inductively coupled plasma source.

### CROSS-REFERENCE TO RELATED APPLICATION

This application claims the benefit under 35 U.S.C. §119(a) of Korean Patent Application No. KR 10-2011-0087908 filed on Aug. 31, 2011, in the Korean Intellectual Property Office, the entire disclosure of which is incorporated herein by reference for all purposes.

### TECHNICAL FIELD

The following description relates to a plasma reactor having an inductively coupled plasma source, and additionally to a plasma reactor having a dual inductively coupled plasma source which can form a via hole at a target substrate by alternately performing an etch process and a deposition process.

### BACKGROUND ART

The integration density of a semiconductor IC is continuously increased and the semiconductor IC has developed thereby. However, recently, a physical limit of two-dimensional integration density causes an attempt to increase three-dimensional integration density.

A typical structure for forming a three-dimensional semiconductor IC is to obtain an electrical connection structure by attaching two dies to each other. One of semiconductor manufacturing techniques for forming the typical structure is a technique for forming a Trough-Silicon Via (TSV) at a semiconductor substrate. A Bosch process is used as one of methods for forming the TSV at the semiconductor substrate.

The Bosch process is to form the TSV at the semiconductor substrate by repeatedly an etch process and a deposition process. However, the Bosch process is known for a negative influence on a next plating process by forming a scalloped surface inside the TSV according to the repeated etch and deposition processes.

Meanwhile, the size of the wafer for manufacturing the semiconductor IC has been continuously increased and substrate processing devices having improved performance has been required. Particularly, in case of a plasma processing apparatus for performing the etch process and the deposition process, the possibility of uniformly processing the large-sized wafer is required.

In case of the plasma reactor having the inductively coupled plasma source, the uniform processing efficiency for the wafer is dependent on the characteristics of the antenna generating the induced electromotive force.

### SUMMARY

An aspect of the present invention is to provide a plasma reactor having a dual inductively coupled plasma source which can efficiently perform a Bosch process as well as a uniform process for a large-sized wafer.

Another aspect of the present invention is to provide a substrate processing method for performing an efficient Bosch process by using a plasma reactor having a dual inductively coupled plasma source.

One aspect of the present invention pertains to a plasma reactor having a dual inductively coupled plasma source. The plasma reactor having the dual inductively coupled plasma source includes: a plasma reactor body having a substrate processing area and a dielectric window which comes in contact with the substrate processing area; and a plasma source including a first antenna for providing first induced electromotive force for generating plasma onto a central area of the substrate processing area through the dielectric window and a second antenna for providing second induced electromotive force for generating the plasma onto an outer area of the substrate processing area, wherein a TSV is formed at a target substrate within the substrate processing area by repeatedly performing a deposition process and an etch process using the plasma generated through the dual inductively coupled plasma source.

In an embodiment of the present invention, the plasma reactor having the dual inductively coupled plasma source includes a grounding electrode unit which is formed between the first antenna and the second antenna and interrupts electromagnetic interference that could occur between the first antenna and the second antenna.

In an embodiment of the present invention, the plasma reactor having the dual inductively coupled plasma source includes a first power supply source for supplying first power to the first antenna and a second power supply source for supplying second power to the second antenna.

In an embodiment of the present invention, the first power supply source generates the first power having frequencies of 1-1000 MHz and the second power supply source generates the second power having frequencies of 1-1000 KHz.

In an embodiment of the present invention, the plasma reactor having the dual inductively coupled plasma source includes a heat-conducting member which is installed at the dielectric window to cover the first antenna or the second antenna and enables the uniform heat distribution of the dielectric window.

In an embodiment of the present invention, the plasma reactor having the dual inductively coupled plasma source includes a ferrite core cover for restricting the magnetic force generated through the second antenna to limit the induced electromotive force generated through the second antenna within the outer area of the substrate processing area.

In an embodiment of the present invention, the plasma reactor having the dual inductively coupled plasma source includes a gas supply nozzle which is installed at a ceiling of the plasma reactor body to supply gas onto the substrate processing area.

In an embodiment of the present invention, the gas supply nozzle has a plurality of injection holes through which two or more different gases are injected.

In an embodiment of the present invention, the gas supply nozzle has two or more separate gas supply paths and can separately supply different gases through the separate gas supply paths.

In an embodiment of the present invention, the plasma reactor having the dual inductively coupled plasma source includes a gas supply ring which is installed in the substrate processing area.

A substrate processing method using the plasma reactor having the dual inductively coupled plasma source according to another feature of the present invention includes the steps of: performing the etch process for the target substrate within the substrate processing area by driving the dual inductively coupled plasma source including the first antenna for forming plasma in the central area of the substrate processing area and the second antenna for forming the plasma in the outer area of the substrate processing area; performing the deposition process for the target substrate by driving the dual inductively coupled plasma source; and forming the TSV at the target substrate by repeatedly performing the etch process and the deposition process.

In an embodiment of the present invention, the dual inductively coupled plasma source has a power range of 1-4 kW in the etch process or the deposition process.

A plasma reactor having an inductively coupled plasma source according to an embodiment of the present invention can perform a uniform process for a large-sized wafer and can efficiently perform a Bosch process by forming plasma using a dual inductively coupled plasma source in a central area and an outer area within a substrate processing area. Other features and aspects may be apparent from the following detailed description, the drawings, and the claims.

### BRIEF DESCRIPTION OF DRAWINGS

FIG. 1 is a view illustrating a constitution of a plasma reactor according to an embodiment of the present invention.

FIG. 2 is a view illustrating a modified example of a constitution of a plasma reactor for driving a dual inductively coupled plasma source using a single power source.

FIG. 3 is a view illustrating a modified structure of a magnetic core cover installed at an antenna coil.

FIGS. 4-8 are views illustrating various embodiments of a gas supply structure of a plasma reactor of the present invention.

### DETAILED DESCRIPTION

In the following detailed description, only certain example embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification. Example embodiments will now be described more fully with reference to the accompanying drawings, in which example embodiments are shown. The invention may, however, be embodied in different forms and should not be construed as limited to example embodiments set forth herein. Rather, example embodiments of are provided so that this disclosure will be thorough and complete, and will fully convey the scope of the invention to those skilled in the art. In the drawings, the sizes of components may be exaggerated for clarity. In each of drawings, the same constitution is indicated by the same reference numeral.

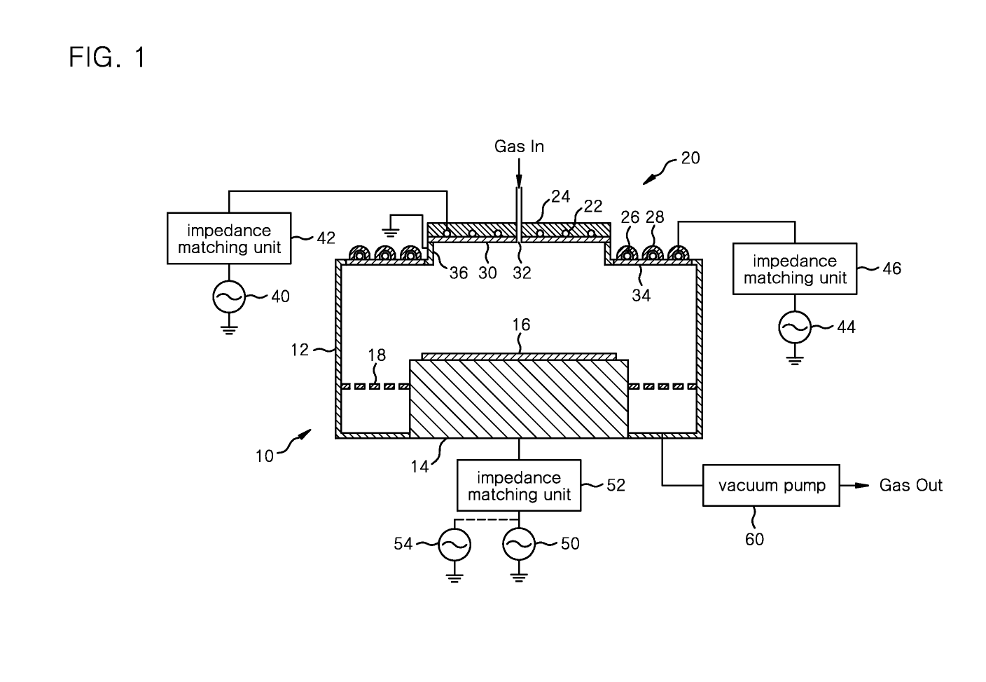

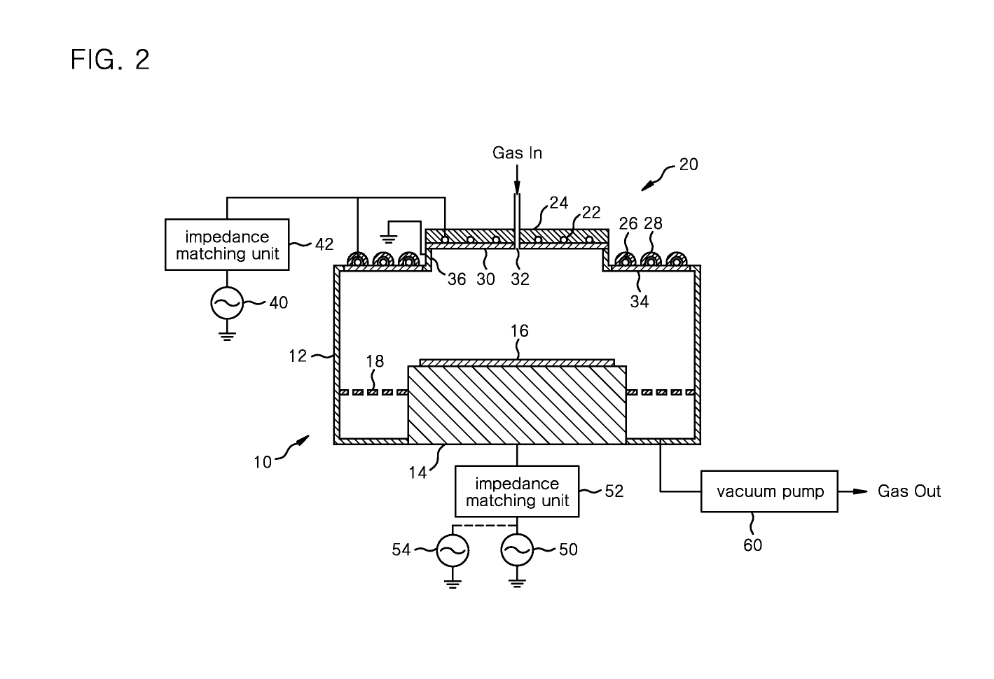

FIG. 1 is a view illustrating a constitution of a plasma reactor according to an embodiment of the present invention and FIG. 2 is a view illustrating a modified example of a constitution of a plasma reactor for driving a dual inductively coupled plasma source using a single power source.

Referring to FIG. 1, the plasma reactor 10 includes a reactor body 12 for providing a substrate processing area and a dual inductively coupled plasma source 20 for providing induced electromotive force for generating plasma onto the substrate processing area. The dual inductively coupled plasma source 20 includes a first antenna 22 for providing the induced electromotive force onto a central area of the substrate processing area and a second antenna 26 for providing the induced electromotive force onto an outer area of the substrate processing area. A substrate supporting plate 14 on which a target substrate 16 is loaded is installed in an internal substrate processing area of the reactor body 12 and an exhaust baffle 18 is installed around the substrate supporting plate 14. The reactor body 12 is connected to a vacuum pump 60 to discharge the air.

A first dielectric window 30 and a second dielectric window 34 are arranged in a central area and an outer area of a ceiling of the reactor body 12, respectively. The first antenna 22 is positioned at an upper part of the first dielectric window 30 and the second antenna 26 is positioned at an upper part of the second dielectric window (34). In the embodiment, the first dielectric window 30 is relatively high positioned in comparison to the second dielectric window 34. However, the first dielectric window (30) may be high or low in comparison with the second dielectric window 36. The relative positions of the first dielectric window 30 and the second dielectric window 34 can be changed to increase substrate processing efficiency for the target substrate. The first and second dielectric windows 30, 34 can be manufactured by one flat panel or different flat panels.

When the power is applied to the first and second antennas 22, 26, the first and second dielectric windows 30, 34, the temperature difference occurs between the areas of the first and second dielectric windows 30, 34 which are close to and are not close to the first and second antennas 22, 26 and polymers can be stacked on the surfaces of the first and second dielectric windows which come in contact with the substrate processing area. To prevent the above effect, a heat-conducting member 24 is molded and installed on the area for the first and second antennas 22, 26. The heat-conducting member 24, for example may be formed with a silicon material. When the first and second antennas 22, 26 are operated by using the heat-conducting member 24, the heat distribution of the first and second dielectric windows 30, 34 can be uniformly formed. The heat-conducting member 24 can be selectively installed on the area on which the first antenna 22 or the second antenna 26 is installed. The stacking effect of the polymers on the first and second dielectric windows 30, 34 for forming the ceiling of the plasma chamber can be prevented by performing a control for heat diffusion uniformity using the heat-conducting member 24.

Meanwhile, the first antenna 22 and the second antenna 26 are formed with hollow type metal tubes and can control the internal temperature of the substrate processing area by supplying the cooling water to the corresponding hollow areas to properly control the temperature in a range of 10-100° C. The temperature for the first and second dielectric windows 30, 34 and the substrate processing area can be properly controlled under the environment in which the substrate processing procedure is performed by operating the dual inductively coupled plasma source 20 with the high electric power during a long time. An etch process and a deposition process for forming a TSV at the target substrate can be stably performed by uniformly diffusing the heat and uniformly controlling the temperature.

The first antenna 22 and the second antenna 26 can be operated by different independent power sources 40, 44, respectively. For example, the first antenna 22 is connected through a first impedance matching unit 42 to a first power supply source 40. The second antenna 26 is connected through a second impedance matching unit 46 to a second power supply source 44. The first power supply source 40 has a frequency of a range of 1-1000 MHz, for example, 13.56 MHz. The second power supply source 40 has a frequency of a range of 1-1000 KHz, for example, 400 KHz. The frequencies of the first and second power supply sources 40, 44 can be changed to different frequencies according to the substrate processing procedure. For example, as shown in FIG. 2, the first and second antennas 22, 26 can be connected serially or in parallel to one power supply source 40.

The plasma processing performance can be reduced by the unexpected mutual electromagnetic interference effect between the plasma generated from the central area of the substrate processing area by the first antenna 22 and the plasma generated from the outer area of the substrate processing area by the second antenna 26. To prevent the unexpected mutual electromagnetic interference effect, a grounding electrode unit 36 for interrupting the electromagnetic interference can be installed between the first antenna 22 and the second antenna 26. Since the electromotive force induced by the first antenna 22 and the second antenna 26 is divided into two parts on the basis of the grounding electrode unit 36 in the substrate processing area, the mutual electromagnetic interference is interrupted. The lowering effect of the plasma processing performance can be effectively prevented by interrupting the mutual electromagnetic interference that could occur between the plasma generated from the central area by the first antenna 22 and the second antenna and the plasma generated from the outer area by the second antenna 26.

The first and second antennas 22, 26 can have various planar arrangement structures. For example, the first and second antennas 22, 26 can have one planar spiral structure or a plurality of planar spiral structures. In addition, the first and second antennas 22, 26 can have a modified structure such as a double layer antenna structure. The first and second antennas 22, 26 can have the planar spiral structure, a single spiral structure, or a plurality of spiral structures. The structures of the first and second antennas 22, 26 can be selected among various structures considering plasma uniformity.

The dual inductively coupled plasma source 20 of the present invention enhances the control performance for the plasma generated from the outside of the substrate processing area by installing a ferrite core cover (28) at the second antenna 26 arranged at the outside. The ferrite core cover 28 can be formed by assembling a plurality of ferrite core pieces having shapes of horseshoes. At this time, the magnetic flux entrance of the ferrite core pieces is arranged toward the substrate processing area. The magnetic flux induced by the second antenna 26 is collected on the ferrite core cover 28 so that the plasma induction is concentrated on the outer area of the substrate processing area. In addition, another ferrite core cover can be installed at the first antenna 22.

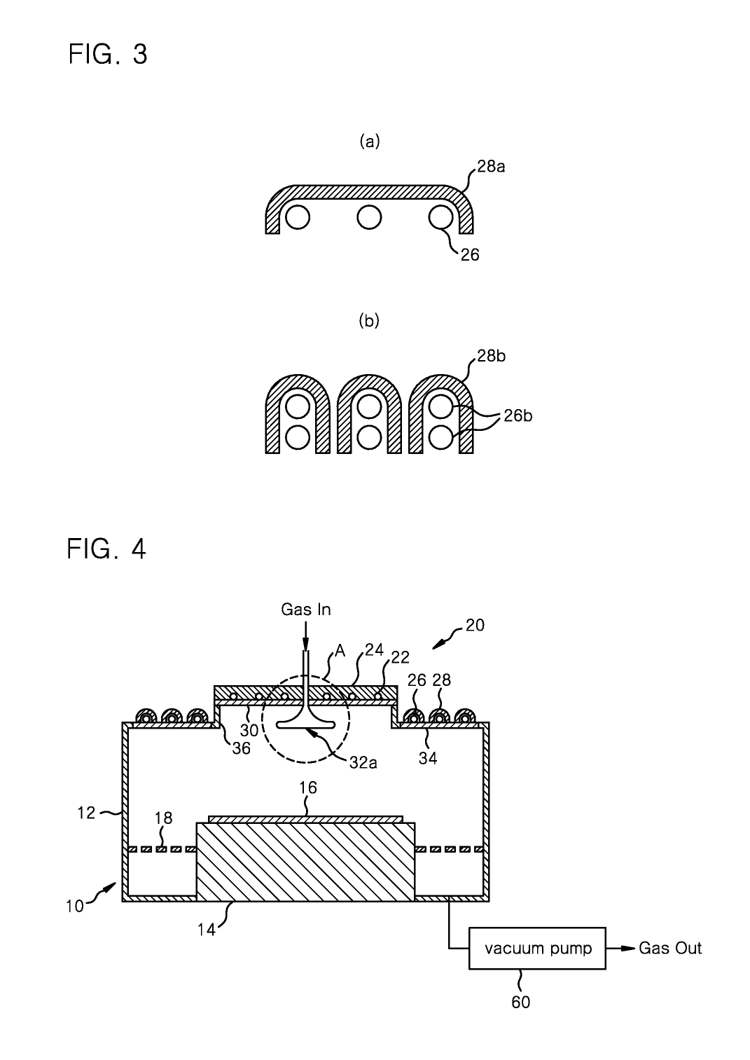

The magnetic core cover 28 installed at the second antenna 26 can be installed at a single antenna line. However, as shown in (a) of FIG. 3, a plurality of antenna lines can be covered by using a magnetic core cover 28a having a widened width. As shown in (b) of FIG. 3, in case of a second antenna 26b having a double layer structure, a double antenna line can be covered by using a magnetic core cover 28b having the increased height corresponding to the height of the second antenna 26b. Thus, the structure of the magnetic core cover 28 can be properly modified according to the structures of the antennas.

Referring to FIG. 1, the substrate supporting plate 14 is connected through a third impedance matching unit 52 to a third power supply source 50. The third power supply source 50 supplies a bias power source to the target substrate 16 on which the substrate supporting plate 14 is loaded. The third power supply source 50 has a frequency of a range of 1-1000 MHz, for example 13.56 MHz. To increase the process efficiency, a fourth power supply source 54 can supply another bias power source through the impedance matching unit 52 to the substrate supporting plate 14. At this time, the third and fourth power supply sources 50, 54 have difference frequencies. Or the substrate supporting plate 14 can be designed as the structure to which the bias power source is not supplied. The substrate supporting plate 14 can be selectively formed with a single bias structure, a multi-bias structure, a biasless structure and the like.

A gas supply nozzle 32 is formed at the center of the ceiling of the plasma reactor 10. The gas supply nozzle 32 is used for supplying a process gas provided from a gas supply source (not shown) to the internal substrate processing area of the plasma reactor 10. The gas supply structure of the plasma reactor 10 of the present invention can be modified in various structures.

FIGS. 4-8 are views illustrating various embodiments of the gas supply structure of the plasma reactor of the present invention.

Referring to FIG. 4, a gas supply nozzle 32a according to an embodiment provides an independent dual gas supply path. The gas supply nozzle includes a multi-injection hole 32a-2 opened in various angles at a nozzle body 32a-1 so as to separately inject the gas in various angles. As the gas is separately injected through the multi-injection hole 32a-1, the uniformity of the plasma formed in the substrate processing area is increased. In addition, the gas supply tube includes an internal supply tube 33-1 and an external supply tube 33-2 to obtain a dual gas supply structure. The internal supply tube 33-1 is connected to the gas supply nozzle 32a. An opening 33-3 of the external supply tube 33-2 is directly exposed to the substrate processing area.

The first gas Gas1 provided through the internal supply tube 33-1 is injected through the gas supply nozzle 32a to the substrate processing area. The second gas Gas2 provided through the external supply tube 33-2 is directly supplied to the substrate processing area. The nozzle body 32a-1 of the gas supply nozzle 32a has a structure in which an upper area is curved. The second gas Gas2 provided through the external supply tube 33-2 is injected along the curved structure of the upper area of the gas supply nozzle 32a and is widely and uniformly injected on the substrate processing area.

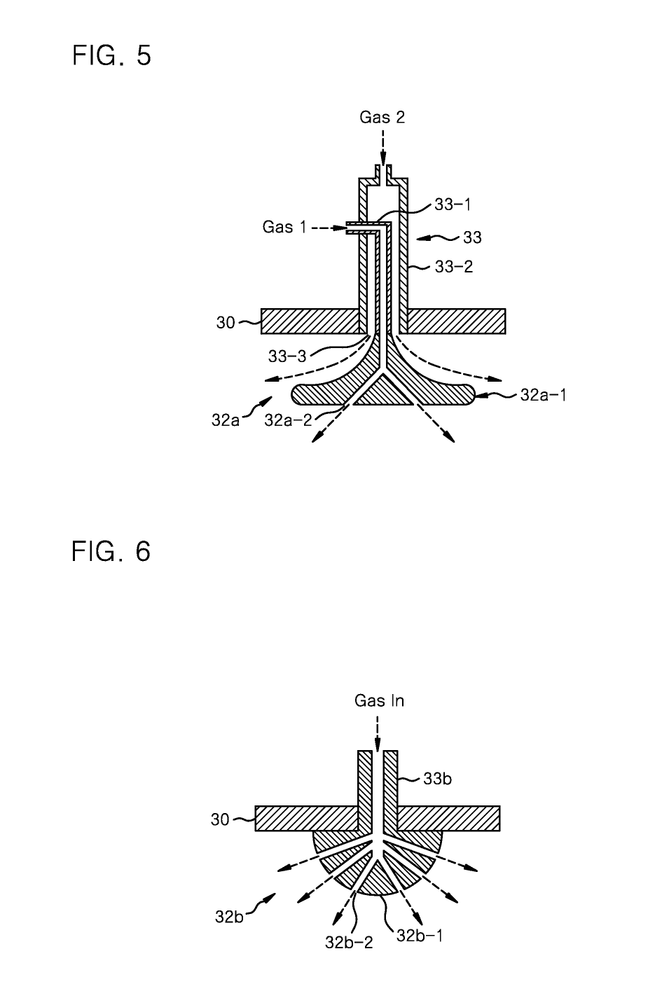

Referring to FIG. 5, a gas supply nozzle 32b according to another embodiment provides a single gas supply path. The gas supply nozzle 32b is connected to a single gas supply tube 33b having one gas supply path. The gas supply nozzle 32b includes a nozzle body 32b-1 having a hemispherical structure and a multi-injection hole 32b-2 which is opened in various angles toward the substrate processing area. In the embodiment, the gas supply nozzle 32b can be effectively used when uniformly injecting the process gas at various angles through the gas supply path which is not independent.

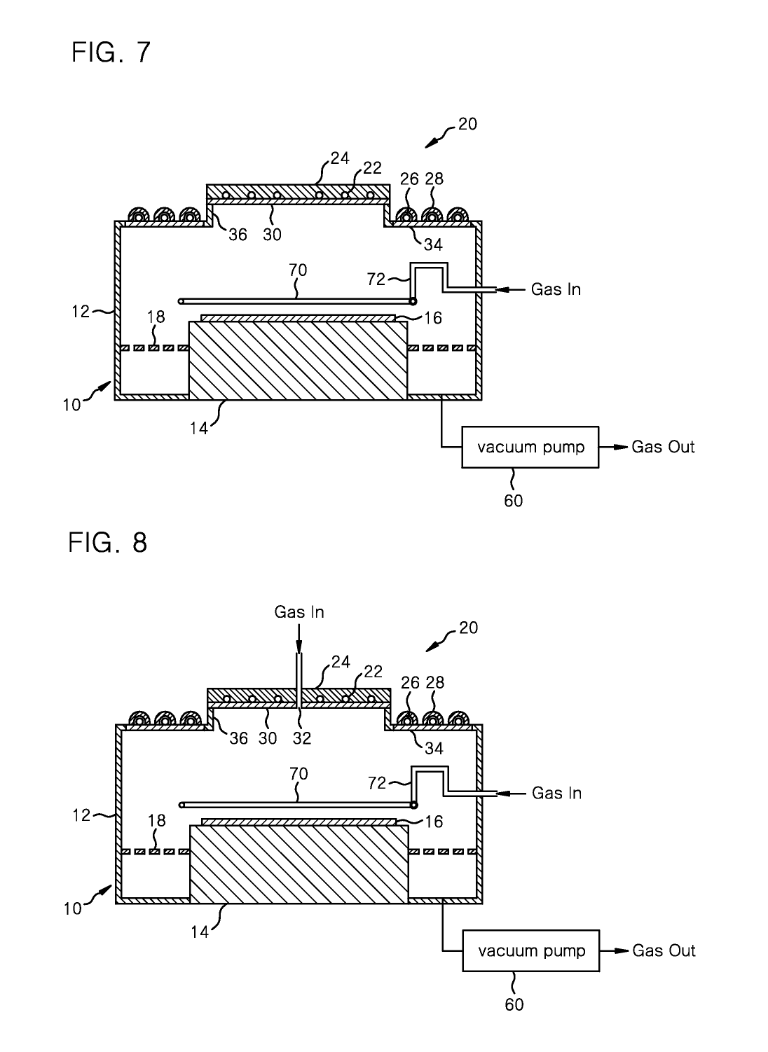

Referring to FIG. 7, the gas supply structure according to another embodiment includes a gas injection ring (70) which is directly positioned in the internal substrate processing area of the plasma reactor 10 in comparison with the above embodiment. The gas injection ring 70 is positioned at an upper part of the target substrate 16 and is connected to the gas supply tube 72 connected from the outside of the reactor body 12 so as to inject the received gas to the substrate processing area. The gas injection ring 70, as shown in FIG. 8, can be installed and used together with the gas supply nozzle 32 installed at the ceiling.

As described above, the plasma reactor 10 having the dual inductively coupled plasma source of the present invention can effectively perform a Bosch process for forming a TSV at the target substrate 16. The uniform plasma is formed in the central area and the outer area of the substrate processing area by using the dual inductively coupled plasma source 20 so that the TSV is formed at the target substrate 16 by repeatedly performing the etch process and the deposition process for the Bosch process.

At this time, the etch process using the dual inductively coupled plasma source 20 is performed under the pressure of 50-200 mT and the power of 1000-4000W. In addition, the etch process is performed by using the gas including SF6 of 500-2000 sccm, Ar of 100-500 sccm, and C4F8 of 1-500 sccm. The deposition process using the dual inductively coupled plasma source 20 is performed under the pressure of 50-100 mT and the power of 1000-4000W. In addition, the deposition process is performed by using the gas including C4F8 of 100-500 sccm.

The forgoing embodiments of the plasma reactor having the dual inductively coupled plasma source of the present invention are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art. For example, the dielectric window is exemplified as the shape of the flat plate but a modified domy structure may be applied thereto.

While this invention has been described in connection with what is presently considered to be example embodiments, it is to be understood that the invention is not limited to the disclosed embodiments, but, on the contrary, is intended to cover various modifications and equivalent arrangements included within the spirit and scope of the appended claims. That is, a number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

### REFERENCE NUMERALS

10: plasma reactor
12: reactor body
20: dual inductively coupled plasma source
22: first antenna
24: heat-conducting member
26: second antenna
28: magnetic core cover
30: first dielectric window
32, 32a, 32b: gas supply nozzle
34: second dielectric window
40: first power supply source
42: first impedance matching unit
44: second power supply source
46: second impedance matching unit

What is claimed is:

1. A plasma reactor having a dual inductively coupled plasma source, comprising:
a plasma reactor body having a substrate processing area and a dielectric window which comes in contact with the substrate processing area; and
a plasma source including a first antenna for providing first induced electromotive force for generating plasma onto a central area of the substrate processing area through the dielectric window and a second antenna for providing second induced electromotive force for generating the plasma onto an outer area of the substrate processing area, wherein a TSV is formed at a target substrate within the substrate processing area by repeatedly performing a deposition process and an etch process using the plasma generated through the dual inductively coupled plasma source.

2. The plasma reactor having the dual inductively coupled plasma source of claim 1, comprising:
a grounding electrode unit which is formed between the first antenna and the second antenna and interrupts electromagnetic interference that could occur between the first antenna and the second antenna.

3. The plasma reactor having the dual inductively coupled plasma source of claim 1, comprising:
a first power supply source for supplying first power to the first antenna; and
a second power supply source for supplying second power to the second antenna.

4. The plasma reactor having the dual inductively coupled plasma source of claim 3, wherein the first power supply source generates the first power having frequencies of 1-1000 MHz and the second power supply source generates the second power having frequencies of 1-1000 KHz.

5. The plasma reactor having the dual inductively coupled plasma source of claim 1, comprising:
a heat-conducting member which is installed at the dielectric window to cover the first antenna or the second antenna and enables the uniform heat distribution of the dielectric window.

6. The plasma reactor having the dual inductively coupled plasma source of claim 1, comprising:
a ferrite core cover for restricting the magnetic force generated through the second antenna to limit the induced electromotive force generated through the second antenna within the outer area of the substrate processing area.

7. The plasma reactor having the dual inductively coupled plasma source of claim 1, comprising:
a gas supply nozzle which is installed at a ceiling of the plasma reactor body to supply gas onto the substrate processing area.

8. The plasma reactor having the dual inductively coupled plasma source of claim 7, wherein the gas supply nozzle has a plurality of injection holes through which two or more different gases are injected.

9. The plasma reactor having the dual inductively coupled plasma source of claim 7, wherein the gas supply nozzle has two or more separate gas supply paths and can separately supply different gases through the separate gas supply paths.

10. The plasma reactor having the dual inductively coupled plasma source of claim 1, comprising:
a gas supply ring which is installed in the substrate processing area.

11. A substrate processing method using the plasma reactor having the dual inductively coupled plasma source comprises the steps of:
performing the etch process for the target substrate within the substrate processing area by driving the dual inductively coupled plasma source including the first antenna for forming the plasma in the central area of the substrate processing area and the second antenna for forming the plasma in the outer area of the substrate processing area;
performing the deposition process for the target substrate by driving the dual inductively coupled plasma source; and
forming the TSV at the target substrate by repeatedly performing the etch process and the deposition process.

12. The substrate processing method using the plasma reactor having the dual inductively coupled plasma source of claim 11, wherein the dual inductively coupled plasma source has a power range of 1-4 kW in the etch process or the deposition process.
